(19) United States
(12) Patent Application Publication
(10) Pub. No.: US 2009/0108329 A1
(43) Pub. Date: Apr. 30, 2009

(54) NON-VOLATILE SEMICONDUCTOR DEVICE AND METHOD OF FABRICATING THE SAME

(75) Inventor: Jae Yun YI, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/967,266

(22) Filed: Dec. 31, 2007

(30) Foreign Application Priority Data
Oct. 31, 2007 (KR) 10-2007-0110717

(51) Int. Cl. H01L 29/788; H01L 21/28

(52) U.S. Cl. 257/321; 438/591; 438/594; 257/E21.179; 257/E29.3; 977/773

(57) ABSTRACT

A non-volatile semiconductor device includes a tunnel insulating film including a ridge and a valley, and a nano floating gate including a nano dot. The ridge and the valley are alternately arranged by a given interval. The nano dot is disposed over the valley of the tunnel insulating film.

### CROSS-REFERENCES TO RELATED APPLICATIONS

The priority of Korean patent application number 10-2007-0110717, filed on Oct. 31, 2007, which is incorporated by reference in its entirety, is claimed.

### BACKGROUND OF THE INVENTION

The present invention relates to a non-volatile semiconductor device. More particularly, the present invention relates to a non-volatile semiconductor device including a nano floating gate and a method of fabricating the same.

A Nano Floating Gate Memory (NFGM) is based on tunneling of flash memory technologies for improving an Electrically Erasable Programmable Read-Only Memory (EEPROM) flash memory technology. This technology is expected to have feasibility down to a 20 nm technology. In a vertical flash memory, nano particles formed between a tunneling insulating film and a control gate insulating film are expected to improve a write/erase speed and a data retention characteristic.

A semiconductor memory can be classified into volatile memory and non-volatile memory. The volatile memory losses stored data when a power supply is disconnected while the non-volatile memory maintains data even when power is not supplied. The non-volatile memory (e.g., a flash memory) has been widely used in mobile communication terminals or mobile data storage devices.

The non-volatile memory can be classified into a stacked gate structure, a notched gate structure and a nano dot gate structure. The stacked gate structure includes a tunnel oxide film, a floating gate, a control gate insulating film and a control gate which are sequentially deposited over a channel region of a semiconductor substrate.

The non-volatile memory having a stacked gate structure uses hot electron injection so that the memory can be programmed. For example, a high voltage is applied to a control gate, and a potential difference is generated between a source and a drain. As a result, thermal electrons are generated in a channel region around the drain, and implanted into the floating gate over an energy barrier of a tunnel oxide film. When the electrons are implanted into the floating gate, a threshold voltage rises. If a voltage smaller than the threshold voltage is applied to the control gate, a current does not flow in a programmed cell so that data can be read.

Electrons of the floating gate are removed by a Fowler-Nordheim (F-N) tunneling mechanism to erase information from the non-volatile memory cell having a stacked gate structure. For example, a high voltage is applied to a source, and 0V is applied to the control gate and the substrate, thereby floating a drain. As a result, a strong electric field is generated between the source and the floating gate to cause F-N tunneling. The floating gate includes a conductive film so that the electrons implanted into the floating gate can be removed by F-N tunneling.

The non-volatile memory having a stacked gate structure has requirements in data retention. For example, the electrons implanted into the floating gate have to be retained in order to maintain programmed information. When there is a pin hole in a tunnel dielectric film, the electrons implanted into the floating gate may be flown out. The floating gate includes a conductive film which may cause a large amount of leakage current from defects in a portion of the tunnel dielectric film.

While the electrons implanted into the floating gate are removed during erasing, the electrons of the floating gate may be over-erased. Since the floating gate includes a conductive film, the electrons may move freely in the floating gate, thereby causing over-erasing.

The nano dot gate structure has been suggested to solve the problems of the stacked gate structure. A nano dot (or nano-scale quantum dot) is formed between the tunnel insulating film and the control gate insulating film so that the nano dot serves as a floating gate. The nano dots are formed of semiconductor materials such as silicon or germanium, and separated by the control gate insulating film. During a program, electrons are implanted into the nano dots which are separated in order to limit electron movement among the nano dots. When a defect occurs in a portion of the tunnel insulating film, a leakage current by the defect affects only the nano dots around the defect. As a result, the nano dot structure improves charge retaining properties of the floating gate.

The electron movement is limited among the nano dots to improve the over-erasing from the erase operation. That is, when the electrons implanted into the floating gate are removed by the F-N tunneling around the source, the over-erasing occurs only in nano dots around the source. A potential of the over-erased nano dots becomes higher so that it becomes difficult to eject the electrons from the over-erased nano dots and perform the erase operation.

The nano dots are formed of conductive materials by a LPCVD method. The nano dot is large in size. The density of the nano dot is increased in some local portion so that a space between the nano dots becomes smaller. As a result, a leakage current between the nano dots is increased and degrades data retention.

### SUMMARY OF THE INVENTION

Embodiments of the present invention are directed to non-volatile semiconductor device. In one embodiment of the present invention, the non-volatile semiconductor device includes a nano floating gate. The non-volatile semiconductor device also includes a tunnel insulating film having a ridge and a valley arranged alternately by a given interval. Accordingly, a process of the non-volatile semiconductor device can be simplified, and a characteristic of the device can be improved.

According to an embodiment of the present invention, a non-volatile semiconductor device includes: a tunnel insulating film including a ridge and a valley, and a nano floating gate including a nano dot. The ridge and the valley are alternately arranged by a given interval. The nano dot is disposed over the valley of the tunnel insulating film.

According to an embodiment of the present invention, a method for fabricating a non-volatile semiconductor device includes: forming a tunnel insulating film including a ridge and a valley over a semiconductor substrate. The ridge and the valley are alternately arranged by a given interval. A nano dot is formed over the valley of the tunnel insulating film. A control gate insulating film is formed over the nano dot and the tunnel insulating film to fill the nano dot. A conductive layer is formed over the control gate insulating film.

### BRIEF DESCRIPTION OF THE DRAWINGS

FIG. 1 is a cross-sectional view of a non-volatile semiconductor device according to an embodiment of the present invention.

FIGS. 2a to 2f are cross-sectional views illustrating a method of fabricating a non-volatile semiconductor device according to an embodiment of the present invention.

FIG. 3 is a conceptual view illustrating a method of fabricating a non-volatile semiconductor device according to an embodiment of the present invention.

### DESCRIPTION OF EMBODIMENTS

The present invention relates to a non-volatile semiconductor device including a nano floating gate. According to an embodiment of the present invention, the non-volatile semiconductor device includes a tunnel insulating film including a ridge and a valley, in which the ridge and the valley are alternately arranged by a given interval.

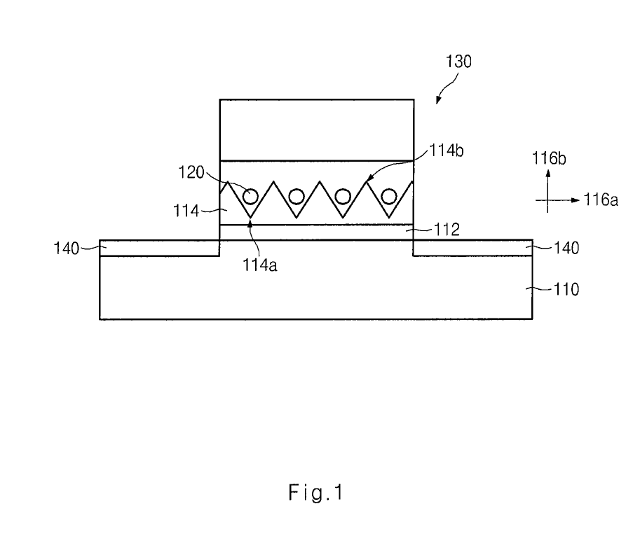

FIG. 1 is a cross-sectional view of a non-volatile semiconductor device according to an embodiment of the present invention. The non-volatile semiconductor device comprises of a semiconductor substrate 110, a gate 130 and a source/drain region 140. Gate 130 includes a nano floating gate structure having a nano dot 120 serving as a floating gate. Nano dot 120 is disposed over a tunnel insulating film that includes a stacked structure of a first tunnel insulating film 112 and a second tunnel insulating film 114.

First tunnel insulating film 112 is formed between semiconductor substrate 110 and second tunnel insulating film 114. Second tunnel insulating film 114 is formed between nano dot 120 and first tunnel insulating film 112. Second tunnel insulating film 114 includes a tetrahedral profile arrangement. For example, second tunnel insulating film 114 includes a profile where a valley 116a and a ridge 116b are alternately arranged in a second direction 114b. Although this embodiment of the present invention shows a 3-dimensional tetrahedral profile arrangement, the present invention is not limited to this arrangement.

Due to second tunnel insulating film 114 including the tetrahedral profile arrangement with a given interval, nano dot 120 can be uniformly formed in size and distribution. As a result, nano dot 120 having the uniform size and distribution is formed between the tunneling insulating film and a control gate insulating film, thereby improving a data write/erase speed and a data retention characteristic.

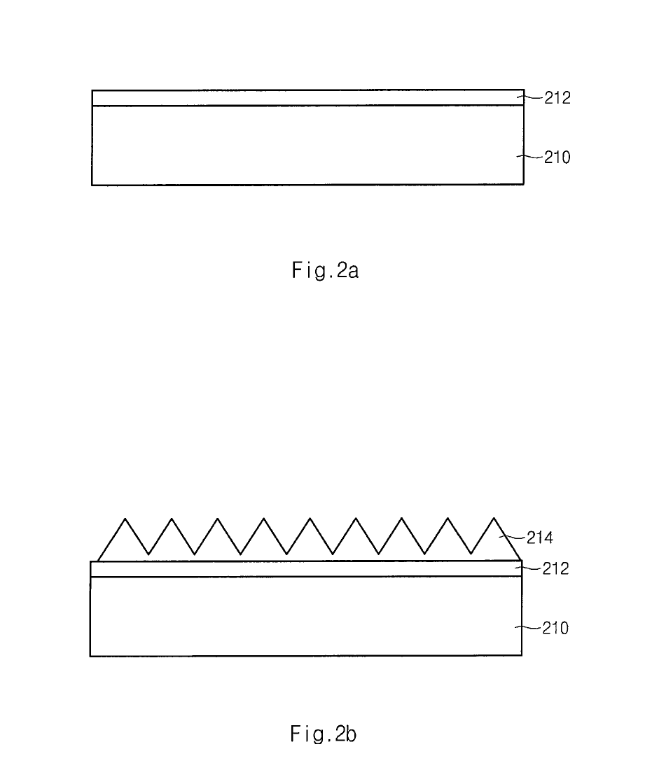

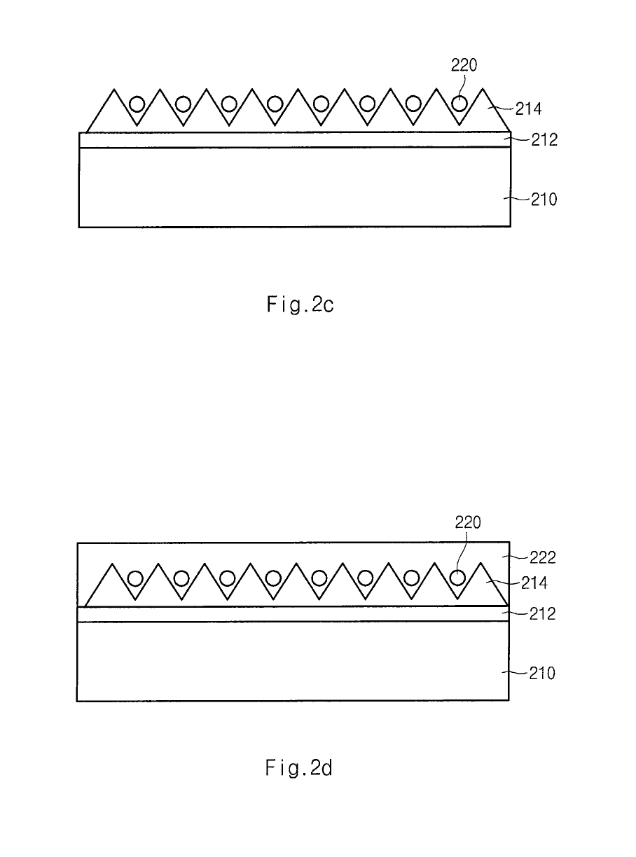

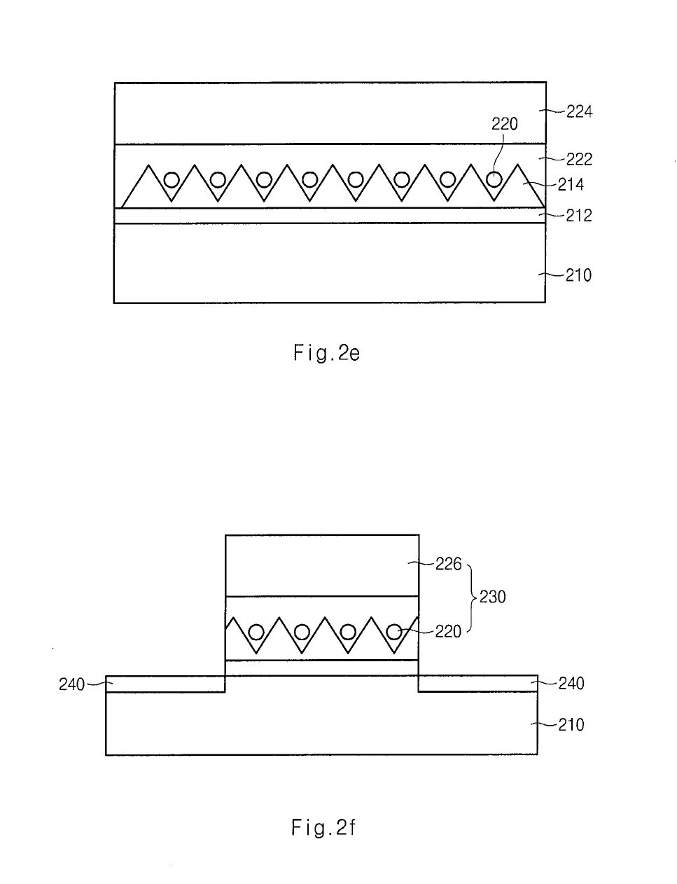

FIGS. 2a to 2f are cross-sectional views illustrating a method of fabricating a non-volatile semiconductor device according to an embodiment of the present invention. A first tunnel insulating film 212 is formed over a semiconductor substrate 210. First tunnel insulating film 212 includes a silicon oxide (SiO₂) film. First tunnel insulating film 212 has a thickness in the range of about 10 Å to 100 Å.

Referring to FIG. 2b, a second tunnel insulating film 214 is formed over first tunnel insulating film 212. Second tunnel insulating film 214 is formed to have a tetrahedral profile arrangement where a ridge and a valley are alternate in a first direction and a second direction (perpendicular to the first direction).

In forming second tunnel insulating film 214 having the tetrahedral profile arrangement, a crystallization temperature and time are regulated to adjust facet size of second tunnel insulating film 214. Depending on the distribution and size of the subsequent nano dot, the facet size is regulated in second tunnel insulating film 214. Second tunnel insulating film 214 is formed of a high dielectric material including a zirconium oxide (ZrO₂) film.

Second tunnel insulating film 214 is formed by a sputtering method, a plasma chemical vapor deposition (PECVD) method, or a low pressure chemical vapor deposition (LPCVD) method. Second tunnel insulating film 214 is formed under a temperature in the range of about room temperature to 600° C. at an atmosphere including one gas selected from Ar, O₂, N₂, and combinations thereof. A ratio of gas injection rates (SCCM) of Ar, O₂, and N₂ ranges from about 6:0.2:0 to 10:3:2.

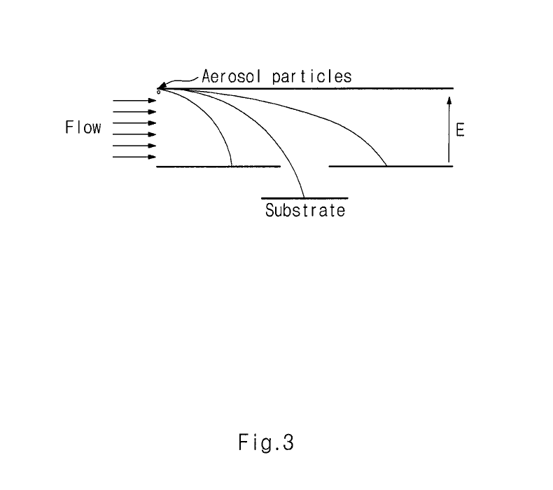

Referring to FIG. 2c, a nano dot 220 is formed over second tunnel insulating film 214. Nano dot 220 is formed by injecting an aerosol nanocrystal. Nano dot 220 may be disposed between valleys of second tunnel insulating film 214. Nano dot 220 can be controlled using a filter by adjusting an electric field and cross-sectional size, so that Nano dot 220 having a cross-section larger than that of second tunnel insulating film 214 is not formed over second tunnel insulating film 214 (see FIG. 3). Nano dot 220 is formed to have a size in the range of about 5 nm to 20 nm.

Nano dot 220 has a stable quantum well by regulating a work function to improve a data retention time. Nano dot 220 includes one material selected from the group consisting of Si, Au, Pt, ZnO, CdTe, CuInSe₂, and combinations thereof.

Referring to FIG. 2d, a control gate insulating film 222 is formed over second tunnel insulating film 214 and nano dot 220 to fill nano dot 220. Control gate insulating film 222 includes a high dielectric material to prevent a leakage current and increase a degree of insulation between a subsequent control gate and nano dot 220. Control gate insulating film 222 includes one film selected from the group consisting of a silicon oxide film (SiO₂), a silicon carbon layer (SiC), a silicon nitride film (SiN), a silicon-rich oxide film, an aluminum oxide film (Al₂O₃), a zirconium oxide film (ZrO₂), a hafnium oxide film (HfO₃), a lanthanum oxide film (La₂O₃), and combinations thereof.

Referring to FIGS. 2e and 2f, a conductive layer 224 is formed over control gate insulating film 222. Conductive layer 224, control gate insulating film 222, second tunnel insulating film 214 and first tunnel insulating film 212 are patterned to form a gate 230 including nano dot 220 and control gate 226. A source/drain region 240 is formed in semiconductor substrate 210 located at both sides of gate 230 with gate 230 as a mask. Conductive layer 224 includes one selected from the group consisting of a polysilicon layer, a tungsten (W) layer and a titanium nitride (TiN) film and combinations thereof.

As described above, according to an embodiment of the present invention, a nano floating gate memory is uniformly formed in size and distribution, thereby improving characteristics of a non-volatile semiconductor device. A tunnel insulating film includes a high dielectric material instead of a silicon oxide film to reduce a leakage current.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non-volatile memory device. Other additions, subtractions, or modifications are obvious in view of the present disclosure and are intended to fall within the scope of the appended claims.

What is claimed is:

1. A non-volatile semiconductor device comprising:
a tunnel insulating film including a ridge and a valley, the ridge and the valley alternately arranged by a given interval; and
a nano floating gate including a nano dot disposed over the valley of the tunnel insulating film.

2. The non-volatile semiconductor device of claim 1, wherein the tunnel insulating film comprises a tetrahedral profile.

3. The non-volatile semiconductor device of claim 2, wherein the tetrahedral profile having a facet, the facet having a size corresponding to a distribution of the nano floating gate.

4. A method for fabricating a non-volatile semiconductor device, the method comprising:
forming a tunnel insulating film including a ridge and a valley over a semiconductor substrate, the ridge and the valley alternately arranged by a given interval;
forming a nano dot over the valley of the tunnel insulating film;
forming a control gate insulating film over the nano dot and the tunnel insulating film to fill the nano dot; and
forming a conductive layer over the control gate insulating film.

5. The method of claim 4, wherein the tunnel insulating film comprises a high dielectric material.

6. The method of claim 5, wherein the high dielectric material comprises a zirconium oxide film.

7. The method of claim 6, wherein the zirconium oxide film is formed under a temperature in the range of about a room temperature to 600° C.

8. The method of claim 6, wherein the zirconium oxide film is formed under an atmosphere including one gas selected from the group consisting of Ar, O₂, N₂, and combinations thereof.

9. The method of claim 8, wherein a ratio of gas injection rates of Ar, O₂, and N₂ in terms of SCCM ranges about 6:0.2:0 to 10:3:2.

10. The method of claim 4, wherein the nano dot is formed by injecting an aerosol nanocrystal.

11. The method of claim 10, wherein during the process of forming the nano dot, a size and distribution of the nano dot is adjusted using an electric field and a dimensions control filter.

12. The method of claim 4, wherein the nano dot comprises one material selected from the group consisting of Si, Au, Pt, ZnO, CdTe, CuInSe₂, and combinations thereof with a thickness in the range of about 5 nm to 20 nm.

13. The method of claim 4, wherein the control gate insulating film comprises a high dielectric material.

14. The method of claim 12, wherein the high dielectric material comprises one selected from the group consisting of a silicon oxide film (SiO₂), a silicon carbon layer (SiC), a silicon nitride film (SiN), a silicon-rich oxide film, an aluminum oxide film (Al₂O₃), a zirconium oxide film (ZrO₂), a hafnium oxide film (HfO₃), a lanthanum oxide film (La₂O₃), and combinations thereof.
